(19) United States
(12) Patent Application Publication
(10) Pub. No.: US 2026/0104448 A1
(43) Pub. Date: Apr. 16, 2026

(54) CIRCUIT DEVICE FOR TESTING SEMICONDUCTOR DEVICE AND METHOD OF OPERATING THE SAME

(71) Applicant: Uxfactory Inc., Gyeonggi-do (KR)

(72) Inventors: Junyoung PARK, Gyeonggi-do (KR); SungSu ROH, Gyeonggi-do (KR); Jihye KIM, Gyeonggi-do (KR)

(21) Appl. No.: 18/941,811

(22) Filed: Nov. 8, 2024

(30) Foreign Application Priority Data
Oct. 11, 2024 (KR) 10-2024-0138187

(51) Int. Cl. G01R 31/28

(52) U.S. Cl. CPC G01R 31/287; G01R 31/2896

(57) ABSTRACT

Disclosed herein are a circuit device for testing a semiconductor device and a method of operating the same. The circuit device includes: a printed circuit board (PCB); a chip socket configured to electrically connect a first semiconductor device to be tested to the PCB in a detachable manner; a second semiconductor device configured to be fixed to the PCB, such that a test code is uploaded thereto, and to apply a test signal to the first semiconductor device according to an operation of the test code and analyze an output signal received from the first semiconductor device; a communication module configured to be fixed to the PCB, to connect an external computing device and the second semiconductor device, and to selectively transmit and receive the test code and analysis results; and a power supply module configured to be fixed to the PCB, and to supply power.

### CROSS-REFERENCE TO RELATED APPLICATION

This application claims the benefit of Korean Patent Application No. 10-2024-0138187 filed on Oct. 11, 2024, which is hereby incorporated by reference herein in its entirety.

### DESCRIPTION OF GOVERNMENT-FUNDED RESEARCH AND DEVELOPMENT

The present disclosure is made with the support of the Ministry of Science and ICT, Republic of Korea, under the following project identifications and numbers:

Project Identification No. 1711170645 and Project No. 2022-0-00266-001, which was conducted in the task named "Development of Low-Bit Precision Hybrid-Mode SRAM PIM for Ultra-Low Power Consumption" in the research project named "Development of Core Technologies for AI Semiconductor PIM Design," by the Research & Business Foundation of Seoul National University, under the research management of the Institute of Information & Communications Technology Planning & Evaluation (IITP), from Apr. 1, 2022, to Dec. 31, 2025.

Project Identification No. 1711170644 and Project No. 2022-0-01037-001, which was conducted in the task named "Development of High-Performance PIM Memory Semiconductor Technology Based on DRAM" in the research project named "Development of Core Technologies for AI Semiconductor PIM Design," by the Korea Advanced Institute of Science and Technology (KAIST), under the research management of the Institute of Information & Communications Technology Planning & Evaluation (IITP), from Apr. 1, 2022, to Dec. 31, 2025.

### BACKGROUND

### 1. Technical Field

The present disclosure relates to a circuit device for testing a semiconductor device and a method of operating the same.

### 2. Description of the Related Art

Application-specific integrated circuits (ASICs) are semiconductor chips designed for specific purposes, and are used in various fields that require high performance and efficiency. The process of developing an application-specific integrated circuit (ASIC) chip is complex and multi-stage, and verification at each stage is essential.

First, a designer defines the functions and required performance of a chip, and then writes specifications based on these definitions. Thereafter, the designer determines data flows and major components by designing the overall architecture of the chip. Then, a logic circuit is coded using a hardware description language (HDL), and this code is converted into a circuit that can be implemented as actual hardware through a synthesis process. The synthesized circuit is tested for errors and subjected to calibration through various tests such as functional verification and timing verification.

The circuit that has been verified in this manner undergoes a physical layout and wiring process, and then, an actual ASIC chip is fabricated. Whether the fabricated chip operates as designed is checked through packaging and function tests. The ASIC chip goes through required reliability and electrical characteristic tests. Finally, the passed ASIC chip is put into mass production.

In a test stage for a chip that has been packaged, whether the manufactured chip operates according to design specifications is checked, thereby ensuring quality and identifying defects. As an example of testing, electrical characteristics may be evaluated by measuring voltage-current characteristics or power consumption, or the timing of clock signals and data signals may be verified by using a timing analysis tool.

In this case, in order to test the packaged chip, a dedicated test board manufactured to fit the size and shape of the chip needs to be used. All the test pins of this test board are fixed. Accordingly, there occurs the inconvenience of having to newly construct a test board in order to conduct tests for a purpose other than an initial design purpose.

In addition, unlike companies that mass-produce ASIC chips, universities and research institutes that test and produce ASIC chips in small quantities find it practically difficult to have all test boards for respective types of chips. Therefore, there is a demand for technology capable of verifying ASIC chips, fabricated in various forms for various purposes, with a single test board.

### SUMMARY

The present disclosure has been conceived in response to the above-described background technology, and is directed to a circuit device for testing a semiconductor device capable of testing various ASIC chips with a single test board and also capable of writing test codes tailored to the requirements of the ASIC chips by including a field-programmable gate array (FPGA), and a method of operating the same.

However, the objects to be accomplished by the present disclosure are not limited to the object mentioned above, and other objects not mentioned may be clearly understood based on the following description.

According to an embodiment of the present disclosure for achieving the above-described object, there is disclosed a circuit device for testing a semiconductor device, the circuit device including: a printed circuit board (PCB); a chip socket configured to electrically connect a first semiconductor device to be tested to the PCB in a detachable manner; a second semiconductor device configured to be fixed to the PCB, configured such that a test code is uploaded thereto, and also configured to apply a test signal to the first semiconductor device according to an operation of the test code and analyze an output signal received from the first semiconductor device; a communication module configured to be fixed to the PCB, to connect an external computing device and the second semiconductor device, and to selectively transmit and receive the test code and analysis results; and a power supply module configured to be fixed to the PCB, and to supply power to the first semiconductor device and the second semiconductor device; wherein the analysis results of the output signal are related to whether the first semiconductor device is operating normally.

Alternatively, the circuit device may further include: a chip connection module configured to be electrically connected to the first semiconductor device through a conductive pattern formed on the PCB; and a second semiconductor device connection module configured to be electrically connected to the second semiconductor device through a conductive pattern formed on the PCB; and the chip connection module and the second semiconductor device connection module may each include a plurality of pins to be selectively connected from the outside of the PCB according to a testing purpose.

Alternatively, the chip socket may be formed to accommodate the first semiconductor device corresponding to a standard specification range.

Alternatively, the first semiconductor device may include an ASIC whose packaging is completed.

Alternatively, the second semiconductor device may include a field-programmable gate array (FGPA).

Alternatively, the plurality of pins of the chip connection module may be arranged along an area alongside each side of the chip socket formed in a square shape.

Alternatively, the plurality of pins of the chip connection module and the plurality of pins of the second semiconductor device connection module may be arranged to face each other.

Alternatively, the power supply modules may include a plurality of power supply modules that are arranged in respective areas alongside the corners of the chip socket to each provide a plurality of fixed voltages having different magnitudes and a variable voltage to the first semiconductor device or the second semiconductor device.

Alternatively, the communication module may include a peripheral component interconnect express (PCIe) terminal configured to check the test results of the first semiconductor device in real time through the external computing device.

Alternatively, the circuit device may further include dynamic random-access memory (DRAM) configured to store intermediate data generated from the second semiconductor device according to the operation of the test code.

Alternatively, the test code may be written according to characteristics of the first semiconductor device or a testing purpose.

According to an embodiment of the present disclosure for achieving the above-described object, there is disclosed a method of testing a semiconductor device in a circuit device, the method including: when a first semiconductor device to be tested is electrically connected to the circuit device in a detachable manner, supplying power to the first semiconductor device and a second semiconductor device configured to test the first semiconductor device; uploading a test code to the second semiconductor device, electrically connected to the circuit device to be fixed thereto, through an external computing device; applying, by the second semiconductor device, a test signal to the first semiconductor device according to the operation of the test code, and analyzing, by the second semiconductor device, an output signal received from the first semiconductor device; and transmitting analysis results related to whether the first semiconductor device is operating normally to the external computing device.

According to the present disclosure, an ASIC chip is tested by means of the circuit device using the FPGA, so that a hardware circuit can be directly configured to meet the requirements of various types of ASIC chips to be tested, thereby optimizing the test environment.

In addition, according to the present disclosure, an ASIC chip to be tested is detachably connected to the PCB, so that a plurality of ASIC chips can be easily replaced and tested with only one circuit device.

### BRIEF DESCRIPTION OF THE DRAWINGS

The above and other objects, features, and advantages of the present invention will be more clearly understood from the following detailed description taken in conjunction with the accompanying drawings, in which:

FIG. 1 is a block diagram showing a circuit device for testing a semiconductor device according to an embodiment of the present disclosure;

FIG. 2 is an exemplary diagram showing a circuit device for testing a semiconductor device according to an embodiment of the present disclosure;

FIG. 3 is a circuit diagram showing part of a circuit device for testing a semiconductor device according to an embodiment of the present disclosure; and

FIG. 4 is a flowchart showing the operation of a circuit device for testing a semiconductor device according to an embodiment of the present disclosure.

### DETAILED DESCRIPTION

Embodiments of the present disclosure will be described in detail below with reference to the accompanying drawings so that those having ordinary skill in the art of the present disclosure (hereinafter referred to as those skilled in the art) can easily implement the present disclosure. The embodiments presented in the present disclosure are provided to enable those skilled in the art to use or practice the content of the present disclosure. Accordingly, various modifications to embodiments of the present disclosure will be apparent to those skilled in the art. That is, the present disclosure may be implemented in various different forms and is not limited to the following embodiments.

The same or similar reference numerals denote the same or similar components throughout the specification of the present disclosure. Additionally, in order to clearly describe the present disclosure, reference numerals for parts that are not related to the description of the present disclosure may be omitted in the drawings.

The term "or" used herein is intended not to mean an exclusive "or" but to mean an inclusive "or." That is, unless otherwise specified herein or the meaning is not clear from the context, the clause "X uses A or B" should be understood to mean one of the natural inclusive substitutions. For example, unless otherwise specified herein or the meaning is not clear from the context, the clause "X uses A or B" may be interpreted as any one of a case where X uses A, a case where X uses B, and a case where X uses both A and B.

The term "at least one of A and B" used herein should be interpreted to refer to all of A, B, and combinations of A and B.

The term "and/or" used herein should be understood to refer to and include all possible combinations of one or more of listed related concepts.

The terms "include" and/or "including" used herein should be understood to mean that specific features and/or components are present. However, the terms "include" and/or "including" should be understood as not excluding the presence or addition of one or more other features, one or more other components, and/or combinations thereof.

Unless otherwise specified herein or unless the context clearly indicates a singular form, the singular form should generally be construed to include "one or more."

The term "N-th (N is a natural number)" used herein can be understood as an expression used to distinguish the components of the present disclosure according to a predetermined criterion such as a functional perspective, a structural perspective, or the convenience of description. For example, in the present disclosure, components performing different functional roles may be distinguished as a first component or a second component. However, components that are substantially the same within the technical spirit of the present disclosure but should be distinguished for the convenience of description may also be distinguished as a first component or a second component.

Meanwhile, the term "module" or "unit" used herein may be understood as a term referring to an independent functional unit processing computing resources, such as a computer-related entity, firmware, software or part thereof, hardware or part thereof, or a combination of software and hardware. In this case, the "module" or "unit" may be a unit composed of a single component, or may be a unit expressed as a combination or set of multiple components. For example, in the narrow sense, the term "module" or "unit" may refer to a hardware component or set of components of a computing device, an application program performing a specific function of software, a procedure implemented through the execution of software, a set of instructions for the execution of a program, or the like. Additionally, in the broad sense, the term "module" or "unit" may refer to a computing device itself constituting part of a system, an application running on the computing device, or the like. However, the above-described concepts are only examples, and the concept of "module" or "unit" may be defined in various manners within a range understandable to those skilled in the art based on the content of the present disclosure.

The term "connected" used herein should be interpreted to include not only a case where components are "directly connected" to each other but also a case where another component is "present" therebetween and a case where they are "electrically connected" to each other with another component interposed therebetween.

The foregoing descriptions of the terms are intended to help to understand the present disclosure. Accordingly, it should be noted that unless the above-described terms are explicitly described as limiting the content of the present disclosure, the terms in the content of the present disclosure are not used in the sense of limiting the technical spirit of the present disclosure.

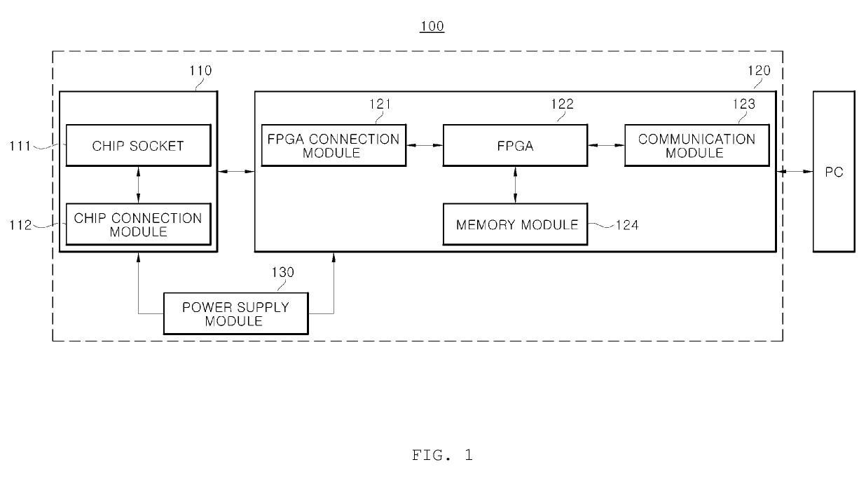

FIG. 1 is a block diagram showing a circuit device 100 for testing a semiconductor device according to an embodiment of the present disclosure.

Referring to FIG. 1, the circuit device 100 for testing a semiconductor device may include a chip mounting module 110, an FPGA setting module 120, and a power supply module 130.

The circuit device 100 refers to a printed circuit board (PCB) including various circuit elements for testing a first semiconductor device. The PCB may include a second semiconductor device that controls the first semiconductor device and performs a test operation. That is, the device to be tested may be the first semiconductor device, and the element to conduct a test may be the second semiconductor device. In the present specification, the first semiconductor device may include an ASIC whose packaging has been completed. The second semiconductor device may be an FPGA. Although descriptions will be given based on these examples in the present specification, the types of semiconductor devices are not limited thereto.

The chip mounting module 110 is configured to connect an ASIC chip to be tested to the PCB so that the ASIC chip can be detachably mounted on the PCB. As an example, the chip mounting module 110 may include a chip socket 111 and a chip connection module 112. As a result, the ASIC chip to be tested may be mounted on the PCB without soldering, so that multiple ASIC chips can be easily replaced and tested with only one circuit device.

The chip socket 111 may be formed to accommodate the first semiconductor device, e.g., an ASIC chip, corresponding to a standard specification range. The chip socket 111 may be implemented as sockets of various types such as a pin grid array (PGA), a land grid array (LGA), and a zero insertion force (ZIF).

The chip connection module 112 includes a conductive pattern formed on the PCB, and may electrically connect the first semiconductor device and the PCB. The chip connection module 112 may be connected to the chip socket 111 by the circuit pattern of the PCB, and may be connected to an FPGA connection module 121 through a connection line outside the PCB. For external connection, the chip connection module 112 may include a plurality of pins.

The FPGA setting module 120 is configured to set and control an FPGA 122 for testing the ASIC chip. For example, the FPGA setting module 120 may include the FPGA connection module 121, the FPGA 122, a communication module 123, and a memory module 124. A code for testing the ASIC chip to be tested is uploaded to the FPGA 122. The FPGA 122 may apply a test signal to the ASIC chip according to the code and analyze a signal output from the ASIC chip. Various test codes may be uploaded to the FPGA 122 according to the characteristics of the ASIC chip, the test content, or the test item. According to the present disclosure, as the circuit device 100 for testing a semiconductor device employs the FPGA 122, a test environment may be optimized by directly configuring a hardware circuit according to the requirements of the ASIC chip to be tested.

The FPGA connection module 121 includes a conductive pattern formed on the PCB, and may electrically connect the FPGA 122, which is the second semiconductor device, and the PCB. The FPGA connection module 121 may be connected to the chip connection module 112 through a connection line outside the PCB. For external connection, the FPGA connection module 121 may include a plurality of pins.

The communication module 123 may include, e.g., a component configured to allow communication between the FPGA 122 and an external PC. The communication module 123 may receive a test code to be uploaded to the FPGA 122 from the external PC, and may transmit the analysis results of the FPGA 122 to the external PC after the completion of the test operation of the ASIC chip. For example, the communication module 123 may include a two-channel UART port. Alternatively, the communication module 123 may include a Peripheral Component Interconnect Express (PCIe) terminal configured to check the test results of the first semiconductor device in real time through an external computing device.

The memory module 124 may temporarily store a test code to be loaded onto the FPGA 122 or data processed by the FPGA 122. For example, when a test signal is applied to the ASIC chip, the results generated as the FPGA 122 analyzes an output signal may be stored in the memory module 124. In other words, the memory module 124 may store intermediate data generated from the second semiconductor device according to the operation of the test code, and may include, e.g., dynamic random-access memory (DRAM).

The memory module 124 may perform a function of temporarily or permanently storing data that is processed by the FPGA 122. In this case, although the memory module 124 may include volatile storage media or nonvolatile storage media, the scope of the present invention is not limited thereto. As used herein, the term "storage medium" refers to a non-transitory computer-readable medium such as a hard disk, flash memory, or other tangible storage device capable of storing data. This excludes transitory signals, such as carrier waves, that are not within the scope of the present invention.

The circuit device 100 according to the present disclosure includes the FPGA 122 and the memory module 124, so that it has the advantage of being able to test large-scale data or data communicated at high speed.

The power supply module 130 may include a plurality of power sources configured to supply power to circuit elements such as the FPGA 122, the memory, and/or the ASIC chip mounted on the PCB. For example, the power supply module 130 may include a plurality of power sources having different voltage levels, and may include a power source providing a variable voltage. For example, the power supply module 130 may provide 1.8 V, 1.0 V, and GND voltages.

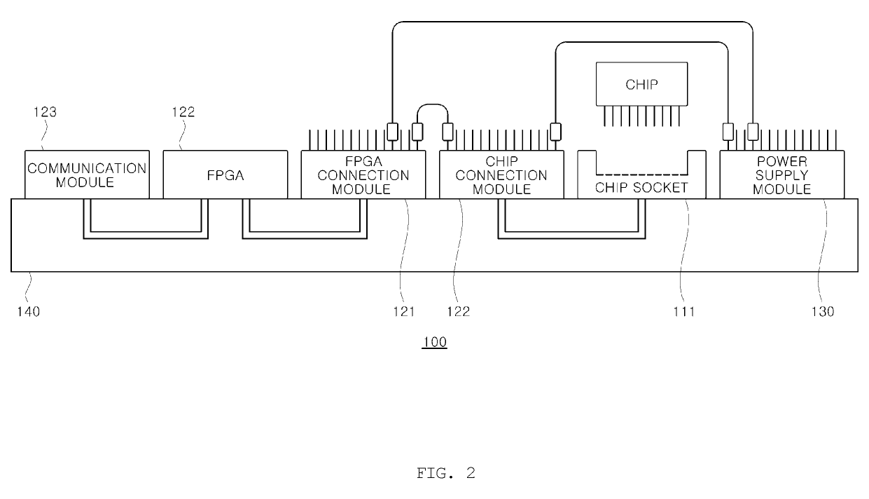

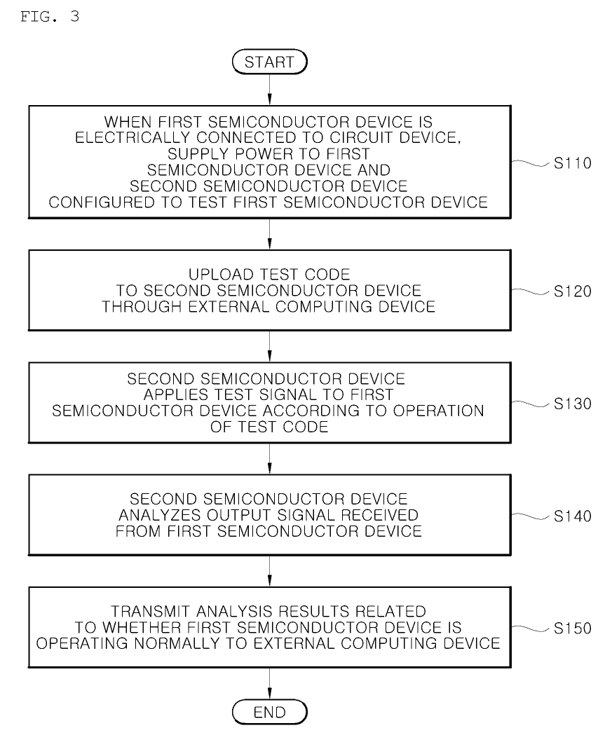

FIG. 2 is an exemplary diagram showing a circuit device for testing a semiconductor device according to an embodiment of the present disclosure, and FIG. 3 is a circuit diagram showing part of a circuit device for testing a semiconductor device according to an embodiment of the present disclosure.

Referring to FIGS. 2 and 3, a circuit device 100 for testing a semiconductor device may include a PCB. The circuit device 100 may further include a chip socket 111 configured to electrically connect a first semiconductor device to be tested to the PCB in a detachable manner. The circuit device 100 may further include a second semiconductor device configured to be fixed to the PCB, to upload a test code, and to apply a test signal to the first semiconductor device according to the operation of the test code and analyze an output signal received from the first semiconductor device. The circuit device 100 may further include a communication module 123 configured to be fixed to the PCB, to connect an external computing device and the second semiconductor device, and to transmit the test code and receive analysis results. The circuit device 100 may further include a power supply module 130 configured to be fixed to the PCB and to supply power to the first semiconductor device and the second semiconductor device. In this case, the analysis results of the output signal may be related to whether the first semiconductor device is operating normally.

Furthermore, the circuit device 100 may further include a chip connection module 112 configured to be electrically connected to the first semiconductor device through a conductive pattern formed on the PCB. Furthermore, the circuit device 100 may further include a second semiconductor device connection module configured to be electrically connected to the second semiconductor device through a conductive pattern formed on the PCB. In this case, the chip connection module 112 and the second semiconductor device connection module may each include a plurality of pins so that they can be selectively connected from the outside of the PCB depending on the test purpose.

A pattern configured to electrically connect the chip socket 111 and the chip connection module 112, a pattern configured to electrically connect the FPGA 122 and the FPGA connection module 121, and a pattern configured to electrically connect the FPGA 122 and the communication module 123 may be printed on the PCB. In addition, the chip connection module 112, the FPGA connection module 121, and the power supply part 130 each include a plurality of header pins protruding outward, and each of the pins may be connected via a jumper pin or a cable.

In this case, based on the square where the chip socket 111 is installed, the FPGA connection module 121 and the chip connection module 112 may be arranged in a form in which they face each other in an area alongside each side of the square. That is, the plurality of pins of the chip connection module 112 may be arranged along an area alongside each side of the chip socket 111 formed in a square shape. Furthermore, the plurality of pins of the chip connection module 112 and the plurality of pins of the FPGA connection module 121 may be arranged to face each other.

A user needs to accurately connect the output pins of the ASIC chip and the output pins of the FPGA 122 to obtain accurate test results. Corresponding pins may be identified at a glance through the form of the arrangement according to the present disclosure, so that the convenience of use can be increased.

In addition, in an area alongside each corner of the square where the chip socket 111 is installed, the plurality of header pins of a power supply module may be arranged. The power supply module 130 may include a plurality of power supply modules 130 that are arranged in respective areas alongside the corners of the chip socket 111 to each provide a plurality of fixed voltages having different magnitudes and a variable voltage to the first semiconductor device or the second semiconductor device. That is, each of the power supply modules 130 may include a set of voltages including a plurality of fixed voltages having different magnitudes and a variable voltage. One set of voltages may be arranged in an area alongside each corner of the square. Through the arrangement of the power supply modules 130, cables on the PCB may be neatly arranged during a test process, and the confusion caused by power supply cables may be prevented.

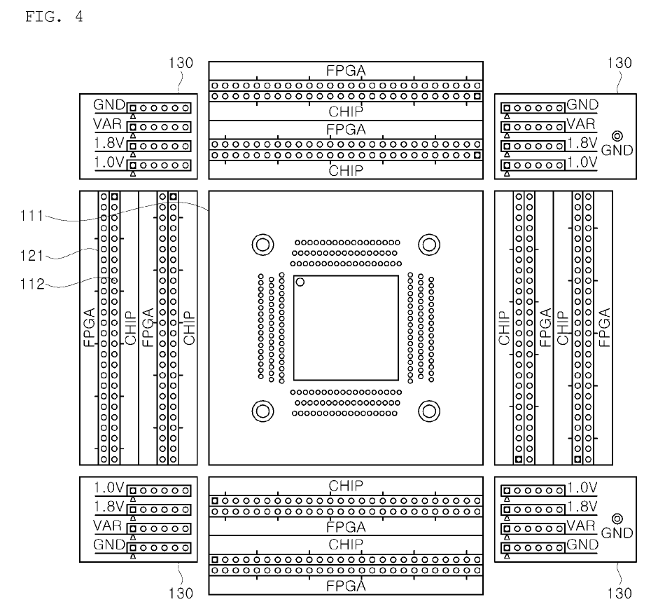

FIG. 4 is a flowchart showing the operation of a circuit device for testing a semiconductor device according to an embodiment of the present disclosure.

Referring to FIG. 4, the first semiconductor device is a chip to be tested, and may correspond to the ASIC chip described above. The second semiconductor device is a chip to perform a test task, and may correspond to the FPGA chip 122 described above.

When the first semiconductor device is electrically connected to the circuit device, the circuit device may supply power to the first semiconductor device and the second semiconductor device testing the first semiconductor device in step S110. For example, a user may mount the first semiconductor device on the chip socket of the circuit device.

In step S110, to supply power of a magnitude and type suitable for the test, the user may connect at least one of the header pins of the power supply module and at least one of the header pins of the chip connection module, and may also connect at least one of the header pins of the power supply module and at least one of the header pins of the FPGA connection module with a cable. Furthermore, at least one of the header pins of the chip connection module and at least one of the header pins of the FPGA connection module may be connected to each other to correspond to the test operation.

Thereafter, power may be supplied to the power supply module of the circuit device from the outside.

The circuit device can upload a test code to the second semiconductor device through an external computing device in step S120. The test code may include a code configured to drive and test the first semiconductor device. The test code may be written and compiled in an external PC and uploaded to the second semiconductor device.

As an example, the test code may include a code configured to check the read/write performance, stability, data integrity and/or the like of the memory to check whether memory embedded in the ASIC chip or an interface with external memory operates appropriately. The test code may include a code configured to check whether the ASIC chip operates appropriately and provides basic output, a code configured to test data transmission speed or stability to test a network interface included in the ASIC chip, and a code configured to test the performance of a CPU equipped in the ASIC chip.

According to the operation of the test code, the second semiconductor device may apply a test signal to the first semiconductor device in step S130, and the second semiconductor device may analyze an output signal received from the first semiconductor device in step S140. Furthermore, the circuit device may transmit analysis results related to whether the first semiconductor device is operating normally to the external computing device in step S150. Accordingly, the user may easily check whether the ASIC chip is operating normally through the external PC.

Meanwhile, in step S150, the analysis results related to the normal operation of the first semiconductor device may be additionally output through an output element, e.g., an LED element, included in the circuit device.

The various embodiments of the present disclosure described above may be combined with one or more additional embodiments, and may be changed within the range understandable to those skilled in the art in light of the above detailed description. The embodiments of the present disclosure should be understood as illustrative but not restrictive in all respects. For example, individual components described as unitary may be implemented in a distributed manner, and similarly, the components described as distributed may also be implemented in a combined form. Accordingly, all changes or modifications derived from the meanings and scopes of the claims of the present disclosure and their equivalents should be construed as being included in the scope of the present disclosure.

What is claimed is:

1. A circuit device for testing a semiconductor device, the circuit device comprising:
a printed circuit board (PCB);
a chip socket configured to electrically connect a first semiconductor device to be tested to the PCB in a detachable manner;
a second semiconductor device configured to be fixed to the PCB, configured such that a test code is uploaded thereto, and also configured to apply a test signal to the first semiconductor device according to an operation of the test code and analyze an output signal received from the first semiconductor device;
a communication module configured to be fixed to the PCB, to connect an external computing device and the second semiconductor device, and to selectively transmit and receive the test code and analysis results; and
a power supply module configured to be fixed to the PCB, and to supply power to the first semiconductor device and the second semiconductor device;
wherein analysis results of the output signal are related to whether the first semiconductor device is operating normally.

2. The circuit device of claim 1, further comprising:
a chip connection module configured to be electrically connected to the first semiconductor device through a conductive pattern formed on the PCB; and
a second semiconductor device connection module configured to be electrically connected to the second semiconductor device through a conductive pattern formed on the PCB;
wherein the chip connection module and the second semiconductor device connection module each include a plurality of pins to be selectively connected from an outside of the PCB according to a testing purpose.

3. The circuit device of claim 2, wherein the chip socket is formed to accommodate the first semiconductor device corresponding to a standard specification range.

4. The circuit device of claim 3, wherein the first semiconductor device includes an application-specific integrated circuit (ASIC) whose packaging is completed.

5. The circuit device of claim 4, wherein the second semiconductor device includes a field-programmable gate array (FGPA).

6. The circuit device of claim 2, wherein the plurality of pins of the chip connection module are arranged along an area alongside each side of the chip socket formed in a square shape.

7. The circuit device of claim 6, wherein the plurality of pins of the chip connection module and the plurality of pins of the second semiconductor device connection module are arranged to face each other.

8. The circuit device of claim 6, wherein the power supply modules include a plurality of power supply modules that are arranged in respective areas alongside corners of the chip socket to each provide a plurality of fixed voltages having different magnitudes and a variable voltage to the first semiconductor device or the second semiconductor device.

9. The circuit device of claim 1, wherein the communication module includes a peripheral component interconnect express (PCIe) terminal configured to check test results of the first semiconductor device in real time through the external computing device.

10. The circuit device of claim 1, further comprising dynamic random-access memory (DRAM) configured to store intermediate data generated from the second semiconductor device according to an operation of the test code.

11. The circuit device of claim 1, wherein the test code is written according to characteristics of the first semiconductor device or a testing purpose.

12. A method of testing a semiconductor device in a circuit device, the method comprising:
when a first semiconductor device to be tested is electrically connected to the circuit device in a detachable manner, supplying power to the first semiconductor device and a second semiconductor device configured to test the first semiconductor device;
uploading a test code to the second semiconductor device, electrically connected to the circuit device to be fixed thereto, through an external computing device;
applying, by the second semiconductor device, a test signal to the first semiconductor device according to an operation of the test code, and analyzing, by the second semiconductor device, an output signal received from the first semiconductor device; and
transmitting analysis results related to whether the first semiconductor device is operating normally to the external computing device.
